(19) United States
(12) Patent Application Publication
(10) Pub. No.: US 2014/0347793 A1
(43) Pub. Date: Nov. 27, 2014

(54) PROTECTIVE CASE AND ELECTRONIC DEVICE USING SAME

(71) Applicants: FIH (Hong Kong) Limited, Kowloon (HK); SHENZHEN FUTAIHONG PRECISION INDUSTRY CO., LTD., Shenzhen (CN)

(72) Inventor: YAN-LING GAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 14/040,874

(22) Filed: Sep. 30, 2013

(30) Foreign Application Priority Data
May 24, 2013 (CN) 201310197443X

(51) Int. Cl. H05K 5/02

(52) U.S. Cl. CPC H05K 5/0204; H05K 5/0234
USPC 361/679.01; 206/45.24

(57) ABSTRACT

A protective case includes a main housing and a bracket. The main housing defines a recess and a retaining groove. The bracket includes a first plate, at least one bracket support, and a second plate. The second plate is slidably received in the retaining groove, and the first plate is received in the recess. The first plate is rotatably connected to the second plate by the bracket support. The first plate is rotated out of the recess to support an electronic device at a desired angle.

### BACKGROUND

1. Technical Field

The exemplary disclosure relates to protective cases, and particularly to a protective case for an electronic device.

2. Description of Related Art

Portable electronic devices can have a protective case to support the electronic device at an angle relative to a surface. However, it can be difficult to change a viewing angle of the electronic device.

Therefore, there is room for improvement within the art.

### BRIEF DESCRIPTION OF THE DRAWINGS

Many aspects of the exemplary protective case and electronic device using the protective case can be better understood with reference to the following drawings. These drawings are not necessarily drawn to scale, the emphasis instead being placed upon clearly illustrating the principles of the present protective case and electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of a protective case for an electronic device according to an exemplary embodiment.

FIG. 2 is a partial exploded view of the protective case of FIG. 1.

FIG. 3 is an exploded view of a bracket of the protective case.

FIG. 4 is an assembled view of the bracket of FIG. 3.

FIG. 5 is a cut-away view of the protective case taken along line V-V in FIG. 1.

FIG. 6 is similar to FIG. 1, but shows the electronic device in a supported state.

### DETAILED DESCRIPTION

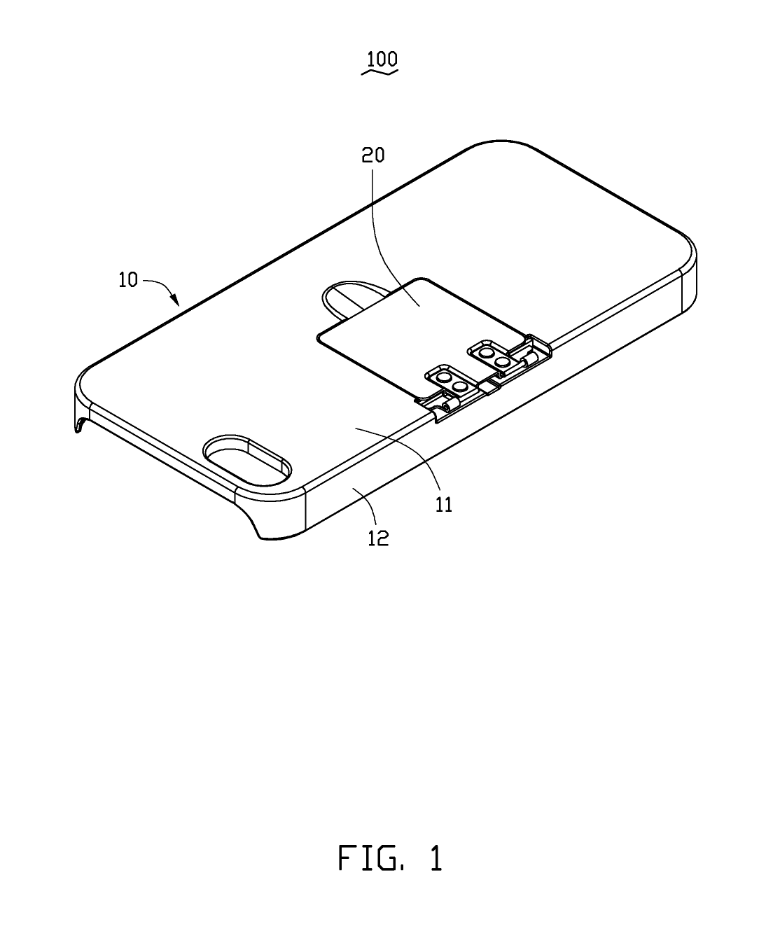

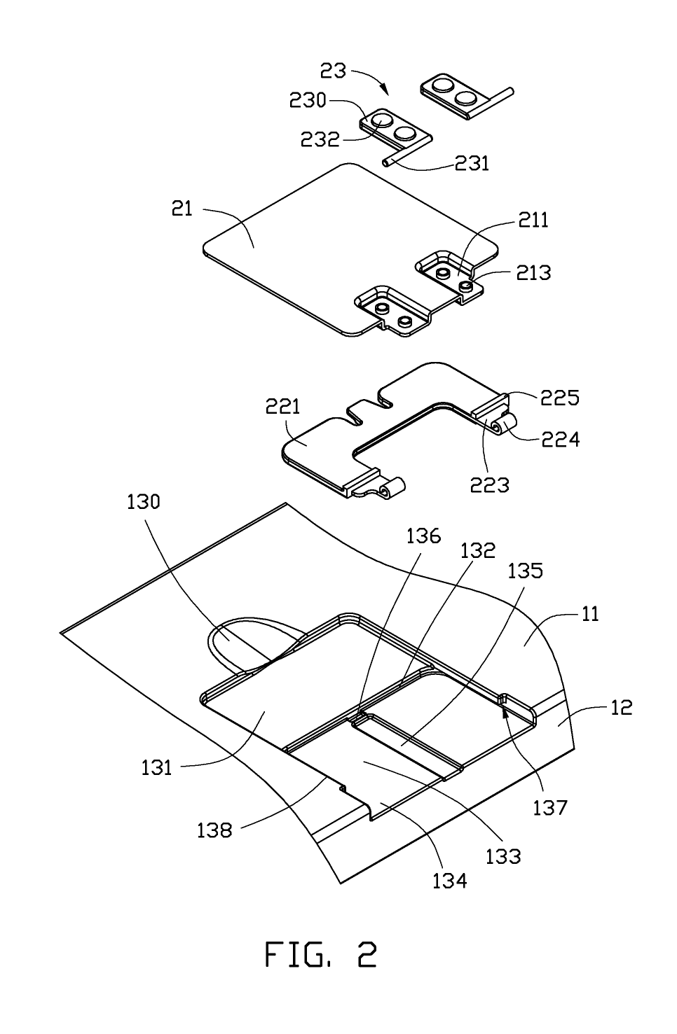

FIGS. 1 and 2 illustrate a protective case 100 used for holding an electronic device, such as a mobile phone. The mobile phone is merely an exemplary application for the purpose of describing details of the protective case 100. The protective case 100 includes a main housing 10 and a bracket 20.

The main housing 10 is configured for receiving the portable electronic device. In this exemplary embodiment, the main housing 10 is substantially rectangular, and includes a base plate 11 and a peripheral wall 12 extending from all sides of the base plate 11. The peripheral wall 12 frictional retains the portable electronic device to the main housing 10. One surface of the main housing 10 (e.g. a back surface) defines a recess 131. A retaining groove 133 is defined in the recess 131 adjacent to the peripheral wall 12. An opening 134 is defined in the retaining groove 133 adjacent to the peripheral wall 12. A stopping edge 132 is formed at one side of the retaining groove 133. A concave portion 130 is formed at one side of the recess 131 opposite to the opening 134. Opposite sides of the retaining groove 133 respectively define a guiding groove 137. An extending edge 138 is above each guiding groove 137. The retaining groove 133 defines an extending groove 135 and a latching groove 136. The extending groove 135 communicates with the opening 134. The latching groove 136 is adjacent to the stopping edge 132 and is spaced from one end of the extending groove 135.

The bracket 20 includes a first plate 21, a second plate 22, and two bracket supports 23. The bracket supports 23 are mounted on the first plate 21 and are pivotably connected to the second plate 22. The second plate 22 is detachably assembled to the main housing 10. As will be described below, the first plate 21 pivotably rotates relative to the second plate 22 to frictionally hold the main housing 10 at predetermined angle relative to a surface. In this exemplary embodiment, the first plate 21 is substantially rectangular and is received in the recess 131. One side of the first plate 21 defines two spaced recessed portions 211. Each recessed portion 211 has two barrel portions 213. Each bracket support 23 has a retaining plate 230 and a shaft 231 formed at one end of the retaining plate 230. The retaining plate 230 has two fastener poles 232. The retaining plate 230 is received in the recessed portion 211, such that the fastener poles 232 are received by the barrel portions 213 to assemble each bracket support 23 to the first plate 21. The fastener poles 232 are further mounted to the first plate portion 21 by welding.

The second plate 22 is configured to pivotably connect to the first plate 21. The second plate 22 includes a base portion 221, two arms 223, and two sleeve portions 224. The base portion 221 is made of plastic and has a clasp 222 at one side. The arms 223 and the sleeve portions 224 extend from another side of the base portion opposite to the clasp 222. The arms 223 and the sleeve portions 224 are made of metal and are integrally formed with the base portion 221 by insert molding. The base portion 221 has a stopping beam 225. Each sleeve portion 224 receives a corresponding shaft 231.

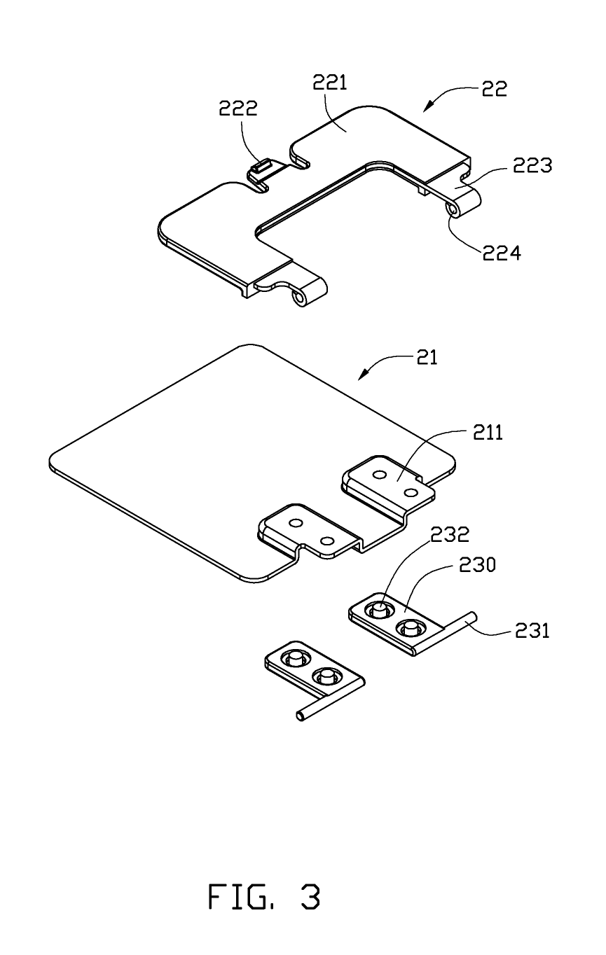

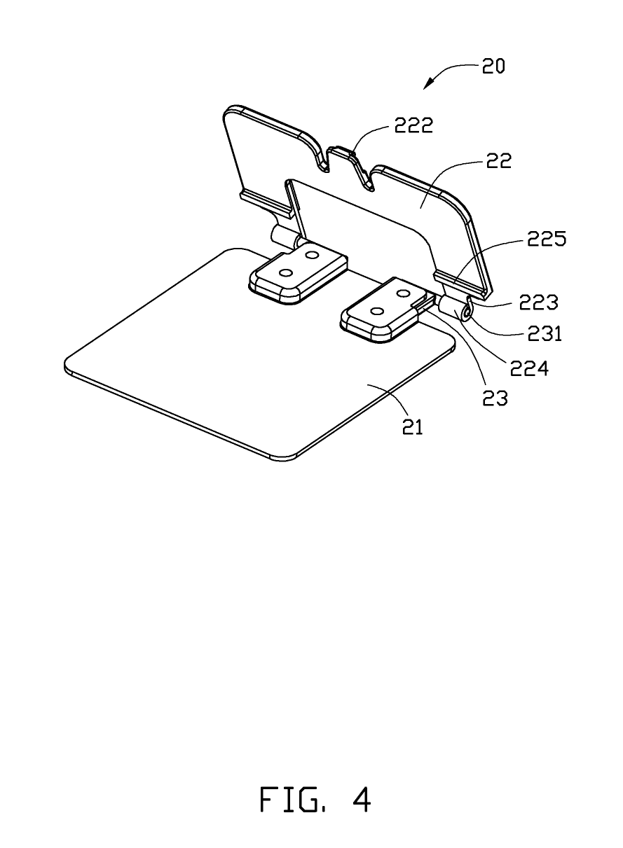

In assembly, referring to FIGS. 3 and 4, the shaft 231 of each bracket support 23 is received by a corresponding sleeve portion 224 of the second plate 22. Then, the retaining plate 230 of each bracket support 23 is received in one of the recessed portions 211. The fastener poles 232 are received by the barrel portions 213 and are mounted to the first plate portion 21 by welding. Accordingly, each bracket support 23 is mounted to the first plate 21. The second plate 22 of the assembled bracket 20 is slid in the guiding grooves 137 from the opening 134, and the clasp 222 slides along the extending groove 135 until one edge of the base portion 221 is stopped by the stopping edge 132 and the clasp 222 is latched in the latching groove 136. Thus, the second plate 22 is assembled in the main housing 10. The first plate 21 is rotated to be received in the recess 131 for covering the second plate 22.

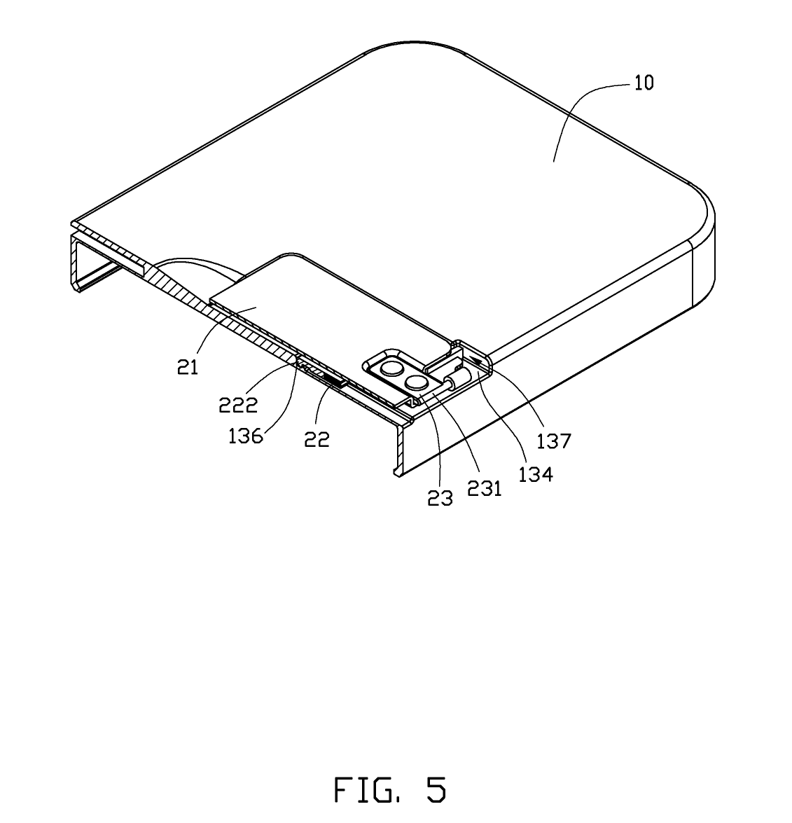

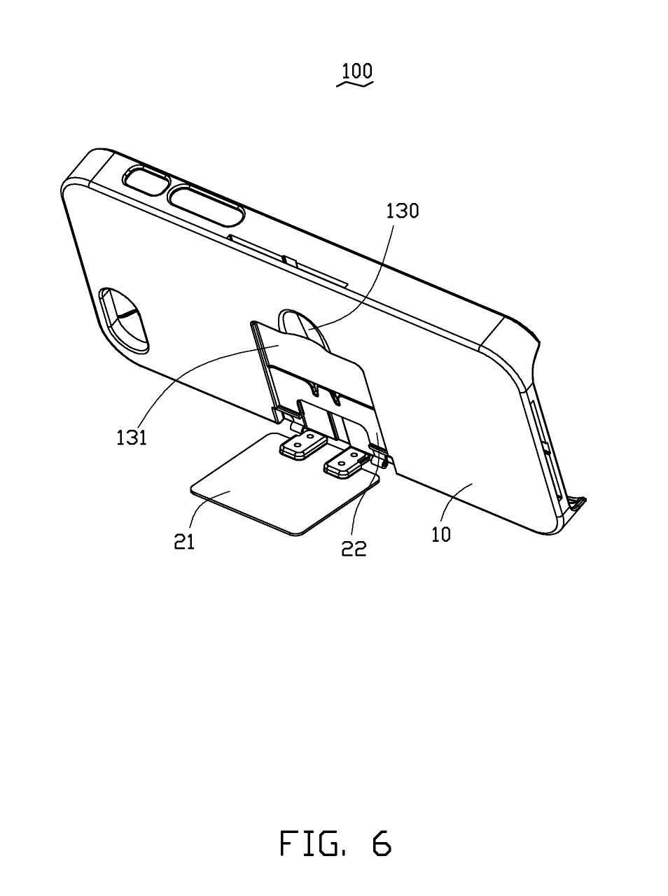

FIG. 6 shows the protective case 100 in a supported state. To support the electronic device at an angle relative to a surface, the first plate 21 is rotated out of the recess 131 and away from the main housing. The concave portion 130 facilitates release of the first plate 21 from the recess 131. The frictional force between the inside of the sleeve portions 224 and their corresponding shafts 231 allow supporting the electronic device at a predetermined angle relative to a surface. When the protective case 100 is in a closed state as shown in FIG. 5, the first plate 21 is rotated toward the main housing 10 to be received in the recess 131 to make the electronic device with the protective case 100 convenient to carry.

The present embodiment of the protective case 100 conveniently supports the electronic device at a desired angle.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A protective case comprising:
a main housing defining a recess and a retaining groove;
a bracket comprising a first plate, at least one bracket support, and a second plate, the second plate received in the retaining groove, the first plate is received in the recess, the first plate rotatably connected to the second plate by the at least one bracket support;
wherein the first plate is rotated out of the recess around the at least one hinge support, and is angled relative to the second plate for supporting an electronic device at a predetermined angle with respect to a support surface.

2. The protective case of claim 1, wherein the retaining groove is defined in the recess, and a stopping edge is formed at one side of the retaining groove.

3. The protective case of claim 2, wherein each of opposite sides of the retaining groove defines a guiding groove, and has an extending edge above each guiding groove, the second plate is slid along the guiding grooves, and the extending edges prevent the second plate from separating from the retaining groove.

4. The protective case of claim 3, wherein the retaining groove defines an extending groove and a latching groove, the latching groove is adjacent to the stopping edge, and is spaced from one end of the extending groove, and the second plate has a clasp latched in the latching groove

5. The protective case of claim 1, wherein there are two bracket supports, the two bracket supports are mounted on the first plate, and are pivotably connected to the second plate.

6. The protective case of claim 5, wherein one side of the first plate defines two spaced recessed portions, each bracket support has a retaining plate and a shaft formed at one side of the retaining plate, the retaining plate is received in the recessed portion to assemble each bracket support to the first plate.

7. The protective case of claim 6, wherein each recessed portion has two barrel portions, the retaining plate has two fastener poles extending therethrough, and the fastener poles extend through the barrel portions and are welded on the first plate.

8. The protective case of claim 6, wherein the second plate includes a base portion, two arms, and two sleeve portions, the arms and the sleeve portions extend from one side of the base portion, each sleeve portion rotatably receives a corresponding shaft therein.

9. The protective case of claim 8, wherein the base portion is made of plastic, and the arms and the sleeve portions are made of metal, and are integrally formed with the base portion by insert molding.

10. The protective cover of claim 8, wherein a friction force created between an inside of each sleeve and its corresponding shaft received in the sleeve, support the electronic device at the predetermined angle relative to a surface.

11. A protective case comprising:
a main housing;
a bracket comprising a first plate and a second plate, the second plate slidably attached to a back of the main housing, the first plate rotatably connected to the second plate;
wherein:
when in a first state, the first plate is rotated and is angled relative to the second plate configured for supporting an electronic device at a predetermined angle;
when in a second state, the first plate is rotated to be coplanar with the back of the main housing for covering the second plate.

12. The electronic device of claim 11, wherein the bracket includes two bracket supports, the two bracket supports are mounted on the first plate, and are pivotably connected to the second plate.

13. The electronic device of claim 12, wherein one side of the first plate defines two spaced recessed portions, each bracket support has a retaining plate and a shaft formed at one side of the retaining plate, the retaining plate is received in the recessed portion to assemble each bracket support to the first plate.

14. The electronic device of claim 13, wherein each recessed portion has two barrel portions, the retaining plate has two fastener poles extending therethrough, and the fastener poles extend through the barrel portions and are welded on the first plate.

15. The electronic device of claim 14, wherein the second plate includes a base portion, two arms, and two sleeve portions, the arms and the sleeve portions extend from one side of the base portion, each sleeve portion rotatably receives a corresponding shaft therein.

16. The electronic device of claim 15, wherein the base portion is made of plastic, and the arms and the sleeve portions are made of metal, and are integrally formed with the base portion by insert molding.

17. The electronic device of claim 15, wherein a friction force created between an inside of each sleeve and its corresponding shaft received in the sleeve, support the electronic device at the predetermined angle relative to a surface.
